(19) United States
(12) Patent Application Publication
(10) Pub. No.: US 2013/0125975 A1
(43) Pub. Date: May 23, 2013

(54) CONDUCTOR INTERFACE

(71) Applicant: First Solar, Inc., Perrysburg, OH (US)

(72) Inventors: Richard S. Malik, JR., Rossford, OH (US); Stephen P. Murphy, Perrysburg, OH (US); Thomas Truman, Toledo, OH (US)

(73) Assignee: FIRST SOLAR, INC., Perrysburg, OH (US)

(21) Appl. No.: 13/682,829

(22) Filed: Nov. 21, 2012

Related U.S. Application Data
(60) Provisional application No. 61/562,139, filed on Nov. 21, 2011.

(51) Int. Cl. H05K 5/02; H01L 31/02; H01L 31/18

(52) U.S. Cl. CPC H05K 5/0247; H01L 31/18; H01L 31/02021
USPC 136/256; 174/535; 174/541; 438/64

(57) ABSTRACT

Disclosed embodiments include a photovoltaic module including a conductor interface for electrically connecting tabs of internal module wiring with external conductors, where the conductor interface includes retention surfaces for retaining the tabs and external conductors in an electrically connected position. Methods of manufacturing a photovoltaic module are also disclosed.

### CROSS-REFERENCE TO RELATED APPLICATION

This application claims the benefit of priority of U.S. Provisional Patent Application Ser. No. 61/562,139 filed on Nov. 21, 2011 hereby incorporated herein by reference in its entirety.

### FIELD OF TECHNOLOGY

The present invention relates to photovoltaic devices having a conductor interface and their methods of manufacture.

### BACKGROUND

Photovoltaic (PV) modules are becoming increasingly popular for providing renewable energy. When a PV module is exposed to sunlight, an electrical current is provided on positive and negative internal busses within the PV module. The internal busses are electrically connected with conductive tabs, which are electrically connected with external conductors within a conductor interface. The external conductors, which may be any appropriate wires or cables suitable for carrying electricity, facilitate connection and transmission of the electrical current generated by the PV module to other electrical devices or loads. The conductor interface, also termed a junction box or cord plate, houses the interconnections of positive and negative internal busses of the PV module with respective external conductors.

PV modules are commonly manufactured with solder connecting the conductive tabs with external conductors. Applying solder to the conductive tabs and external conductors, however, requires an additional manufacturing step, as well as additional quality control to ensure that the solder is placed in the correct location. Accordingly, it is desirable to provide an alternative reliable and efficient manufacturing process for PV modules.

### BRIEF DESCRIPTION OF THE DRAWINGS

FIGS. 1A and 1B illustrate top and bottom perspective views of an example photovoltaic module.

FIG. 2 illustrates a cross-sectional view of the photovoltaic module of FIGS. 1A and 1B taken along section A-A.

FIG. 3 illustrates an exploded top view of a conductor interface for a photovoltaic module, in accordance with embodiments described herein.

FIGS. 4A-4D illustrate a top perspective view of a process for manufacturing a photovoltaic module, in accordance with embodiments described herein.

FIGS. 5A-5E illustrate a cross-sectional view of a process for manufacturing a photovoltaic module, in accordance with embodiments described herein.

FIG. 6 illustrates a cross-sectional view of a photovoltaic module, in accordance with embodiments described herein.

FIG. 7 illustrates a cross-sectional view of a photovoltaic module, in accordance with embodiments described herein.

FIGS. 8A and 8B show textured surfaces of a conductor interface, in accordance with embodiments described herein.

FIGS. 9A-9C illustrate cross-sectional views of portions of a conductor interface, in accordance with embodiments described herein.

FIG. 10 illustrates a cross-sectional view of a photovoltaic module including a conductor interface, in accordance with embodiments described herein.

FIG. 11 illustrates a cross-sectional view of a photovoltaic module including a conductor interface, in accordance with embodiments described herein.

FIG. 12 illustrates a top-down view of multiple electrically connected photovoltaic modules, in accordance with embodiments described herein.

### DETAILED DESCRIPTION

In the following detailed description, reference is made to the accompanying drawings which form a part hereof, and which illustrate specific embodiments of the invention. These embodiments are described in sufficient detail to enable those of ordinary skill in the art to make and use them. It is also understood that structural, logical, or procedural changes may be made to the specific embodiments disclosed herein.

Described embodiments include a photovoltaic (PV) module having a conductor interface where the conductor interface includes retention surfaces for retaining one or more conductors in position within the conductor interface. One or more retention surfaces may be provided on either a base or cover portion, or both, of the conductor interface, such that when the base and cover portions are engaged with one another, an electrical connection is maintained between conductors within the conductor interface.

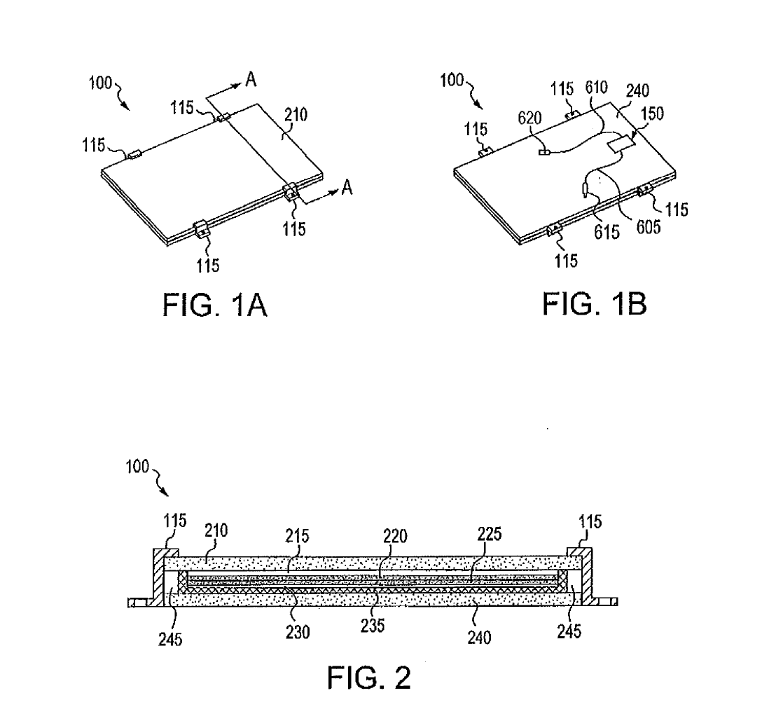

FIGS. 1A and 1B show a top perspective view and a bottom perspective view, respectively, of an example PV module 100. The PV module 100 can be a cadmium telluride (CdTe) module, a copper indium gallium diselenide (CIGS) module, a crystalline silicon module, or any other type of PV modules.

Module 100 is oriented to receive sunlight through a front layer 210. The sunlight is then converted to electricity within the module using semiconductors. To facilitate this conversion process, module 100 can include a plurality of PV cells formed between front layer 210 and back plate 240. The cells can be connected in series, parallel, or a combination thereof depending on the desired electrical output from module 100.

Front layer 210 is the outermost layer of the module 100 and may be exposed to a variety of temperatures and forms of precipitation. Front layer 210 is also the first layer that incident light encounters upon reaching module 100. Consequently, front layer 210 may be composed of a material that is both durable and highly transparent, such as, for example, borosilicate glass, soda lime glass, or float glass.

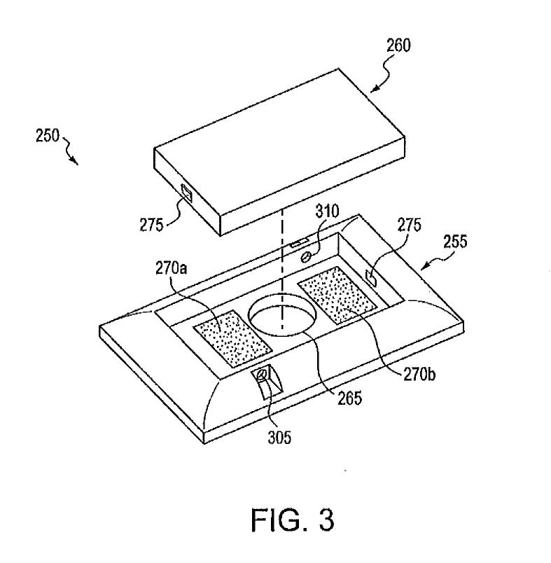

Back plate 240 together with front layer 210 encloses module 100 with an edge-insulating seal 245 (FIG. 2) provided between them. Back plate 240 can be composed of any suitable protective material, such as a glass or substrate, for example, borosilicate glass, float glass, soda lime glass, carbon fiber, or polycarbonate. Back plate 240, front layer 210, and insulating seal 245 protect the plurality of layers of module 100 from moisture intrusion, physical damage, and environmental hazards.

External conductors 605, 610 facilitate connection and transmission of the electrical current generated by module 100 to other electrical devices or loads. External conductors 605, 610 may be any appropriate wires or cables suitable for carrying electricity, and may include insulating jackets surrounding their conductive core. External conductors 605, 610 may include industry-standard connectors 615, 620 for ease of installation and interconnection with other electrical devices. As shown in FIG. 1B, a conductor interface 150, also termed a junction box or cord plate, installed on back plate 240 of module 100 houses the interconnections of positive and negative internal busses of module 100 with respective external conductors 605, 610. Brackets 115 connected to module 100 (for example, to peripheral edges of front layer 210 and back plate 240) may be used to fix module 100 to a support structure.

FIG. 2 shows a cross-sectional view of one simplified example of a module 100 taken along section A-A. As shown in FIG. 2, each PV cell within module 100 can include a plurality of layers. The exemplary module 100 includes a front contact layer 215 formed adjacent to front layer 210, a semiconductor window layer 220 formed adjacent to front contact layer 215, a semiconductor absorber layer 225 formed adjacent to window layer 220, a back contact layer 230 formed adjacent to absorber layer 225, an interlayer 235 formed adjacent to back contact layer 230, a back plate 240 provided adjacent to interlayer 235, and the insulating seal 245 formed between front layer 210 and back plate 240 in an area between the edge of layers 215-235 and the peripheral edge of front layer 210 and back plate 240. The various layers can be laser-scribed after formation of the various module layers to form a plurality of interconnected photovoltaic cells within module 100.

The interlayer 235 may be composed of any suitable material, such as ethylene vinyl acetate (EVA). Interlayer 235 serves several functions, including serving as a moisture barrier between back plate 240 and the rest of the layers of module 100, as an electrical insulator between the plurality of layers of module 100 and back plate 240, and/or as a bonding agent for bonding back plate 240 to module 100.

Insulating seal 245 is provided in an area between the edge of layers 215-235 and the peripheral edge of front layer 210 and back plate 240. Insulating seal 245 may be light transmissive and formed of a polymer material that is selected from a group consisting of polycarbonate, acrylic, silicone, and polyurethane.

In PV module 100, a p-n junction is formed where semiconductor absorber layer 225 abuts semiconductor window layer 220. When PV module 100 is exposed to sunlight, photons may be absorbed within the p-n junction region. As a result, photo-generated electron-hole pairs may be created. Movement of the electron-hole pairs produces an electrical current on positive and negative internal busses within module 100, which are connected to conductive tabs that exit module 100 through an opening in back plate 240. The conductive tabs are electrically connected with external conductors 605, 610 (FIG. 1B) within the conductor interface 150.

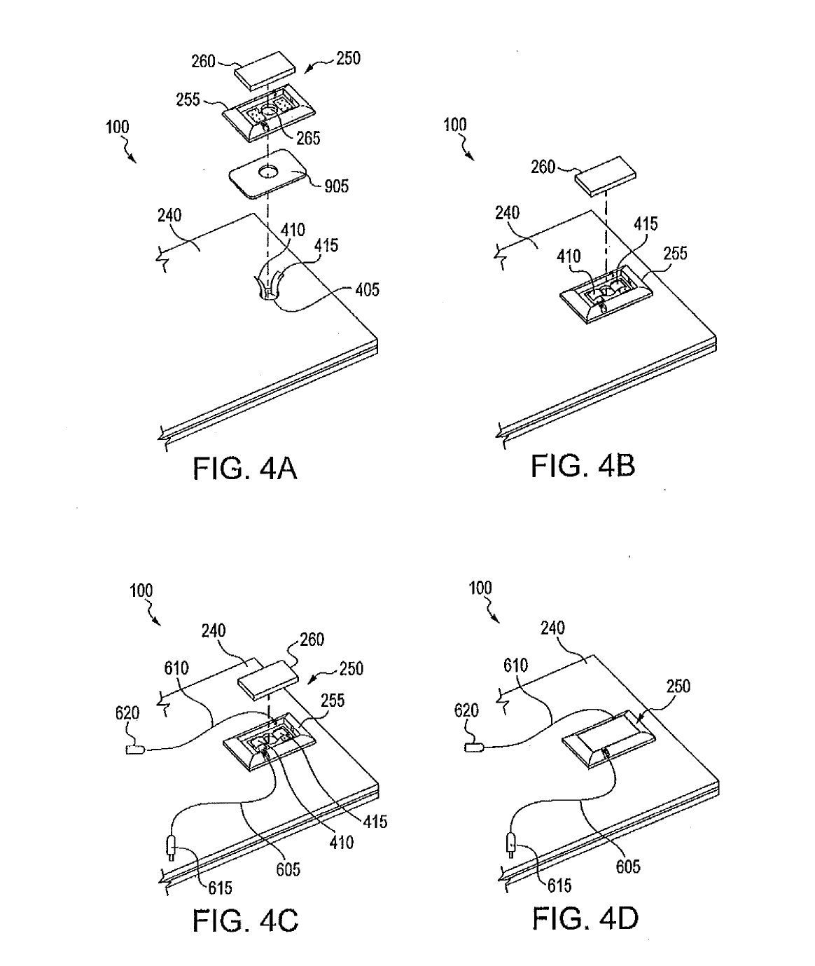

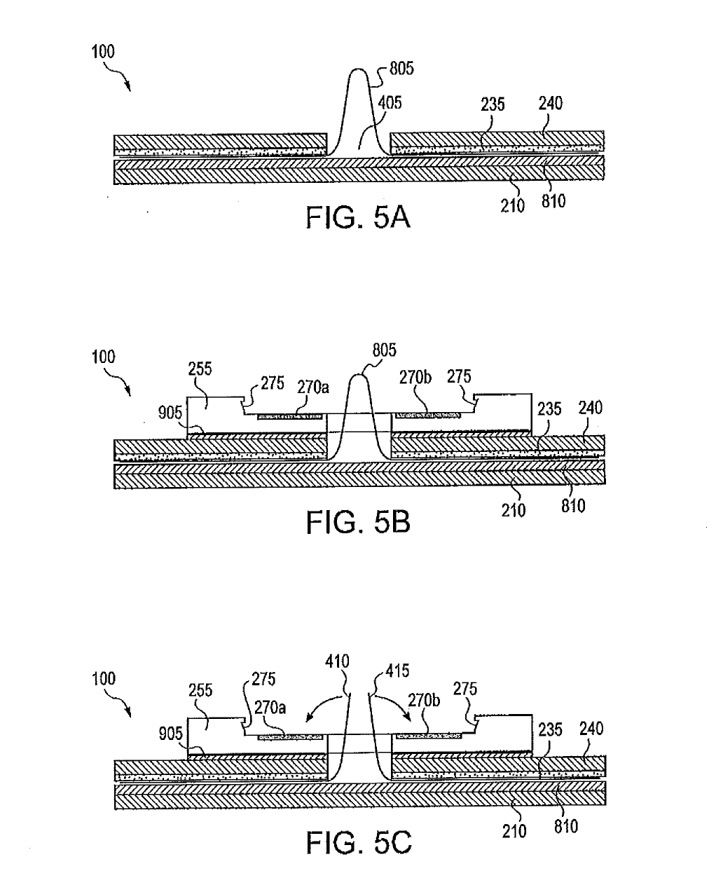

FIG. 3 is an exploded top view of one embodiment of a conductor interface 250 for PV module 100. As described further below, conductor interface 250 can be installed over an opening in the back plate 240 of the PV module 100 that exposes the conductive tabs 410, 415 (FIG. 4A) that are connected to internal busses of the PV module 100 to secure and house the interconnections of the conductive tabs 410, 415 with external conductors.

Conductor interface 250 includes a base portion 255 and a cover portion 260. Base portion 255 may include an opening 265 (e.g., an aperture), through which conductive tabs 410, 415 (FIG. 4A) of a module extend.

Base portion 255 may also include first and/or second through-holes 305, 310, through which external conductors 605, 610 (FIG. 4C) may extend. In one example, first and second through-holes 305, 310 may be configured to accommodate external conductors 605, 610 that are formed from any appropriate types of wire or cable capable of carrying electricity, and that may include insulating jackets surrounding their conductive core.

Base portion 255 also includes retention surfaces 270a and 270b for fixing a position of a wire or other conductor. As shown in FIG. 3, a first retention surface 270a may be arranged next to first through-hole 305 on a first side of opening 265, and a second retention surface 270b may be arranged next to second through-hole 310 on a second side of opening 265.

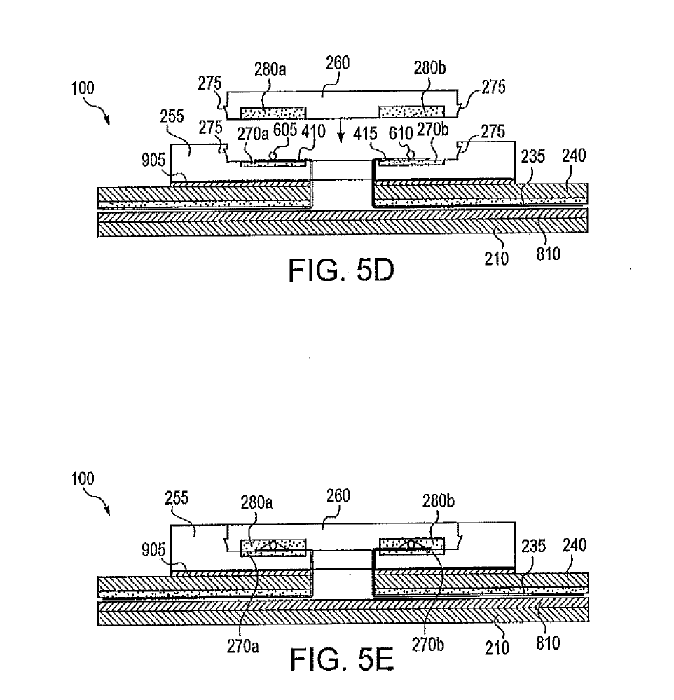

In conductor interface 250, retention surfaces 270a, 270b are textured surfaces, such as molded high-friction textured surfaces formed of plastic, or textured surfaces formed of fabric or other suitable material, that are configured to capture and retain conductors (e.g., conductive tabs 410, 415 and/or external conductors 605, 610 in FIGS. 5D and 5E) inserted on the surface. In another embodiment, one or more of the retention surfaces 270 may comprise an adhesive material. In yet another embodiment, one or more of the retention surfaces 270 may comprise a textured conductive material for providing and/or enhancing an electrical connection between conductors inserted on the surface.

Retention surfaces 270a, 270b can have any suitable dimensions. In one example, for a PV module 100 having overall dimensions of a width of approximately 60 cm and a length of approximately 120 cm, base portion 255 may have a width in a range of approximately 20 mm to 100 mm, and a length in a range of approximately 40 mm to 120 mm, first and second surfaces 270a, 270b may each have widths and lengths in a range of approximately 10 mm to 20 mm, although it should be understood that other suitable dimensions are also within the scope of this disclosure.

Cover portion 260 may also include retention surfaces 280a, 280b (FIG. 5D-5E) that correspond to first and second retention surfaces 270a, 270b of base portion 255. Each retention surface 280a, 280b of cover portion 260 may also be a molded textured surface, or a textured surface formed of fabric or other suitable material, or a textured conductive surface, that is configured to capture and retain conductors (e.g., tabs wires) in contact with the surface. For example, each retention surface 280a, 280b of cover portion 260 may be a textured surface, such as a suitable high-friction surface (e.g., saw-tooth designs, crimping designs, or similar types of textured surfaces) designed to mate (e.g., physically and fittingly engage) with a corresponding textured surface (e.g., retention surfaces 270a, 270b on base portion 255). In another embodiment, one or more of the retention surfaces 280a, 280b may comprise a conductive material and/or an adhesive material.

Base portion 255 and cover portion 260 may include a cover retention feature 275 configured to retain cover portion 260 to base portion 255. Cover retention feature 275 can include any suitable retention feature such as, for example, a snap, clip, lock, seal, fastener, press fit, friction fit, or snap fit. Cover retention feature 275 may be designed to permit disassembly of cover portion 260 from base portion 255, or, alternatively, may be designed not to allow for easy disassembly, for example, in order to discourage vandalism after module 100 (FIG. 4A) has been installed in the field.

Using retention surfaces 270a, 270b and/or retention surfaces 280a, 280b, the external conductors 605, 610 (FIG. 1B) and/or the respective tabs 410, 415 (FIG. 4A) for the internal bussing system that are connected within conductor interface 250 can be electrically connected in contact with one another and retained in a desired position (e.g., operably connected, electrically and physically) without an additional manufacturing step of applying solder or other material to fix the external conductors 605, 610 to tabs 410, 415 within conductor interface 250.

A process for manufacturing a PV module 100 with a conductor interface 250 is now described in connection with FIGS. 4A-4D and FIGS. 5A-5E. FIGS. 4A-4D illustrate a top perspective view of the process. FIGS. 5A-5E illustrate a cross-sectional view of the process. The module 100 includes a front layer 210, a semiconductor window layer 220, an interlayer 235, and a back plate 240. It should be understood that while, for purposes of clarity, only front layer 210, interlayer 235, and back plate 240 are labeled in FIGS. 5A-5E, module 100 may include other layers, such as those discussed above in connection with FIG. 2, as well as any other layers that may be used in forming photovoltaic cells.

As shown in FIG. 4A, module 100 includes a back plate 240 with a back plate opening 405, through which module conductive tabs 410, 415, which are connected to internal module wiring, are exposed. For example, first and second conductive tabs 410, 415 are connected to respective positive and negative internal busses within module 100.

As shown in FIGS. 4A and 4B, first and second conductive tabs 410, 415 may be inserted through back plate opening 405, and then partially folded back towards opposing sides of back plate opening 405, in order to prevent shorting between tabs 410, 415. In another embodiment, as shown in FIGS. 5A and 5B, a loop 805 of an internal foil or tape conductor may be formed having respective ends connected to respective internal module busses that extend through opening 405. Loop 805 may then be severed to form the first tab 410 and the second tab 415, resulting in substantially the same arrangement as shown in FIG. 4A. Alternatively, as shown in FIG. 5B, base portion 255 of connector interface 250 may be affixed to back plate 240 prior to severing loop 805, with opening 265 arranged such that loop 805 extends through opening 265. Loop 805 may then be severed to form the first tab 410 and the second tab 415. Other arrangements for forming and using tabs 410, 415 that connect with internal bussing of module 100 may also be used.

As shown in FIG. 4B and FIG. 5B, base portion 255 of connector interface 250 is affixed to back plate 240, with opening 265 arranged such that either first and second tabs 410, 415 (FIG. 4B) or severable loop 805 (FIG. 5B) extend through opening 265. Base portion 255 may be affixed to back plate 240 using, for example, an adhesive material 905, such as a dual-sided adhesive foam tape, a silicon sealant, or other suitable adhesive materials.

At least a portion of each conductive tab 410, 415 is then folded back against a respective one of first and second retention surfaces 270a, 270b, as shown in FIGS. 4B and 5C, such that the conductive tabs 410, 415 rest on retention surfaces 270a, 270b, respectively.

As shown in FIGS. 4C and 5D, external conductors 605, 610 are inserted into conductor interface 250 through a respective one of through-holes 305, 310 (FIG. 3). At least a conductive portion of the first and second external conductors 605, 610 rests on a respective one of the first and second tabs 410, 415 to directly form an electrical connection between an external conductor 605, 610 and a respective tab 410, 415 resting on the respective retention surfaces 270a, 270b. External conductors 605, 610 may be any appropriate electrically conductive wires or cables, and may include insulating jackets surrounding their conductive core along most of their respective lengths, with a portion of each external conductor 605, 610 exposed for electrically connecting to a respective one of tabs 410, 415. On an opposite end, external conductors 605, 610 may include respective industry-standard connectors 615, 620 for ease of installation and interconnection with other electrical devices.

In another embodiment, retention surfaces 270a, 270b include a conductive material, such that first and second external conductors 605, 610 need not physically contact first and second tabs 410, 415, respectively, but rather may be operably electrically connected to a respective one of first and second tabs 410, 415 when secured by the same retention surfaces 270a, 270b.

As shown in FIGS. 4D and 5E, cover portion 260 is affixed to base portion 255. As shown in FIG. 5E, cover portion 260 may also include respective first and second retention surfaces 280a, 280b arranged in locations corresponding to first and second retention surfaces 270a, 270b, respectively, of base portion 255. For example, a textured first retention surface 280a on cover portion 260 can mesh with a textured first retention surface 270a on base portion 255, thereby retaining first tab 410 and first external conductor 605 in an electrically connected arrangement. Similarly, a textured second retention surface 280b on cover portion 260 can mesh with a textured second retention surface 270b on base portion 255, thereby retaining second tab 415 and second external conductor 610 in an electrically connected arrangement. In one embodiment, a textured material of each retention surface 280a, 280b of cover portion 260 may be designed to mechanically mate with a corresponding textured material of retention surface 270a, 270b of base portion 255. In another embodiment, one or more of the retention surfaces 270a, 270b, 280a, 280b may comprise an adhesive material. In another embodiment, one or more retention surfaces 270a, 270b, 280a, 280b include a conductive material capable of operably electrically connecting respective first and second external conductors 605, 610 to respective first and second conductive tabs 410, 415 without a direct physical connection between them.

Once cover portion 260 is affixed to base portion 255, such as through retention feature 275, a clamping force is exerted upon tabs 410, 415 and external conductors 605, 610 by cover portion 260 and base portion 255, and particularly by the respective opposing retention surfaces 270a, 280a, and 270b, 280b. This clamping force retains first tab 410 in electrical contact with first external conductor 605 and second tab 415 in electrical contact with second external conductor 610. For example, retention surfaces 270a, 280a may physically clamp first tab 410 to a conductive portion of external conductor 605 to maintain the electrical contact, or if one of retention surfaces 270a, 280a is conductive, retention surfaces 270a, 280a may retain first tab 410 and external conductor 605 on the conductive retention surface to maintain the electrical contact. The retention surfaces 270a, 270b, 280a, 280b prevent tabs 410, 415 and/or external conductors 605, 610 from moving during completion of manufacture and module 100 field installation, and thereby prevent open connections from forming between one of tabs 410, 415 and a respective one of external conductors 605, 610.

Once cover portion 260 is affixed to base portion 255, an optional step of injecting potting material into conductor interface 250 to fill, or nearly fill, the interior of conductor interface 250 may be performed. Injected potting material in conductor interface 250 can provide a further moisture barrier preventing moisture from reaching interior surfaces of module 100, can serve as an insulating material and prevents short circuiting between first and second tabs 410, 415, and/or can provide further structural support to the components housed within conductor interface 250. Potting material may be injected into an interior of conductor interface 250, for example, through an auxiliary opening in cover portion 260 or base portion 255, or one of through-holes 305, 310 (FIG. 3).

Embodiments described above eliminate the need for soldered connections between tabs 410, 415 and external conductors 605, 610 within conductor interface 250, while providing the benefit of maintaining the respective positions of the tabs 410, 415 and external conductors 605, 610 during manufacture, installation, and use of the module 100. The soldering step in the manufacturing process of module 100 can thereby be eliminated, resulting in an efficient manufacturing process while reliably maintaining the desired position for the internal and/or external conductors.

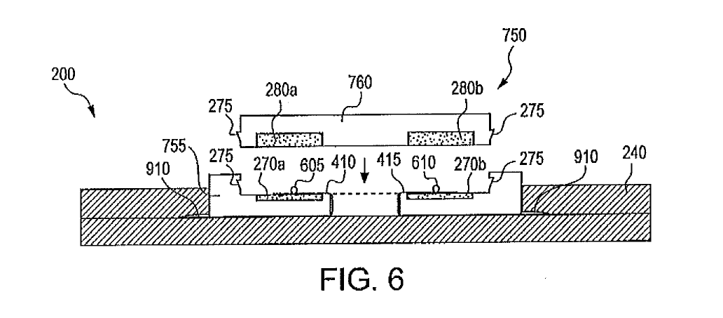

FIG. 6 shows a cross-sectional view of another embodiment of a module 200 including a conductor interface 750. Conductor interface 750 includes a base portion 755 designed to fit within an opening in back plate 240, such as an opening 705 that exposes tabs 410, 415. Base portion 755 is connected by a flange 910 to an interior surface of back plate 240 and/or to one or more interior layers of module 100, for example, between an interior surface of back plate 240 (i.e., a surface of back plate 240 that will face interior layers of module 200) and an interlayer 235 (FIG. 2). During manufacture of module 200, flange 910 may be sealed to the interior surface of back plate 240 prior to affixing back plate 240 to module 200, using a sealant such as a silicon sealant, an epoxy, or other appropriate sealant, in order to provide a moisture seal for module 200.

Base portion 755 includes first and second retention surfaces 270a, 270b, upon which first and second tabs 410, 415 can be folded back and secured in place. Conductor interface 750 also includes a cover portion 760 that includes first and second retention surface 280a, 280b corresponding to first and second retention surface 270a, 270b of base portion 755. Retention surfaces 270a, 270b, 280a, 280b are textured surfaces, such as a molded textured surface formed of plastic, or a textured surface formed of fabric, or other suitable material, that is suitably configured to capture and retain conductors (e.g., wires) inserted on the surface, such as opposing saw-tooth designs, hook-and-loop designs, crimping designs, or similar types of mating textured surfaces.

Base portion 755 and cover portion 760 are configured to interconnect, such as by engaging cover retention features 275 on cover portion 760 and base portion 755, such that retention surfaces 270a, 270b and/or retention surfaces 280a, 280b retain external conductors 605, 610 and tabs 410, 415 within conductor interface 750 in desired electrical connection without an additional manufacturing step of applying solder or other material to fix the external conductors 605, 610 to tabs 410, 415 within conductor interface 250. As with embodiments described above in connection with FIGS. 3-5, retention surfaces 270a, 270b and/or 280a, 280b can be conductive so the external conductors 605, 610 and tabs 410, 415 need not be in direct physical contact for an electrical connection to be made between them.

In addition to physically and operatively retaining connections between internal tabs 410, 415 and external conductors 605, 610, conductor interface 750 provides a low profile outer surface for back plate 240 because conductor interface 700 protrudes less than a comparable-sized conductor interface affixed to an exterior surface of the back plate 240, allowing for efficient stacking of multiple PV modules for storage or transport.

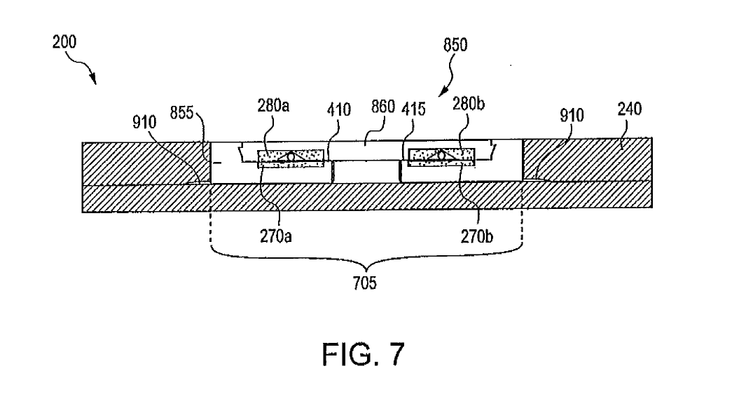

FIG. 7 shows a cross-sectional view of module 200 including another embodiment of a conductor interface 850. Conductor interface 850 includes a base portion 855 and cover portion 860 that are both designed to substantially fit entirely within an opening in back plate 240, such as an opening 705 that exposes tabs 410, 415. As with conductor interface 750 described with reference to FIG. 6, base portion 855 of conductor interface 850 is connected by a flange 910 to an interior surface of back plate 240 and/or to one or more interior layers of module 100, such as an interlayer 235 (FIG. 2). Base portion 855 also includes first and second retention surfaces 270a, 270b, upon which first and second tabs 410, 415 can be folded back and secured in place. Cover portion 860 includes first and second retention surface 280a, 280b corresponding to first and second retention surface 270a, 270b of base portion 855. Conductor interface 850 does not substantially protrude from back plate 240, providing a PV module 200 with a substantially flush back plate 240 for even further efficiency in stacking of multiple PV modules during storage or transport.

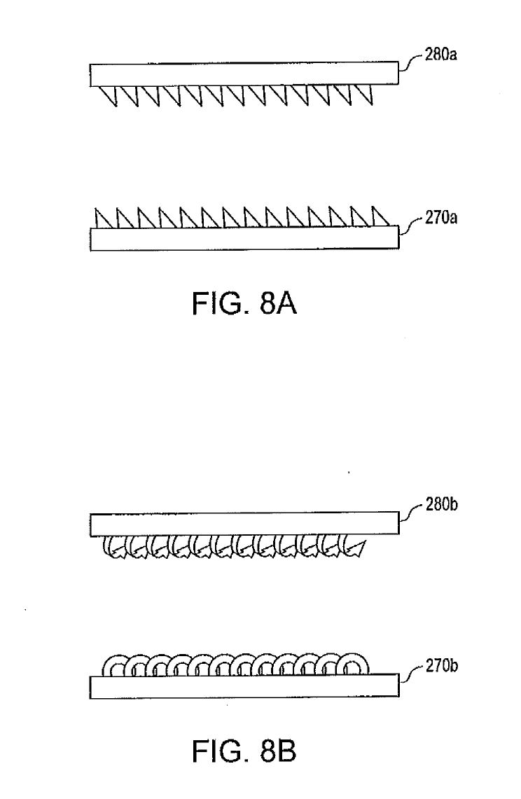

FIGS. 8A and 8B show textured surfaces 270a, 270b, 280a, 280b that may be employed in embodiments described above. For example, in some embodiments, as shown in FIG. 8A, textured surfaces 270a (e.g., of a base portion 255 of conductor interface 250) and corresponding textured surface 280a (e.g., of a cover portion 260 of conductor interface 250) may be flexible and formed having complementary sawtooth designs that physically and fittingly lockingly engage one another when pressed together (e.g., when base portion 255 is affixed to cover portion 260 in FIG. 5E), thereby mating the textured surfaces 270a, 280a. In other embodiments, as shown in FIG. 8B, textured surface 270b may be flexible and formed having a loop configuration, and corresponding textured surface 280b may be flexible and formed having a hook configuration, such that the opposing loops and hooks physically and fittingly engage one another when textured surfaces 270b, 280b are pressed together. In other embodiments, one or both of textured surfaces 270a, 280a, or one or both of textured surfaces 270b, 280b may include conductive material in order to provide an electrical connection between two conductors retained by the textured surface without the two conductors physically touching.

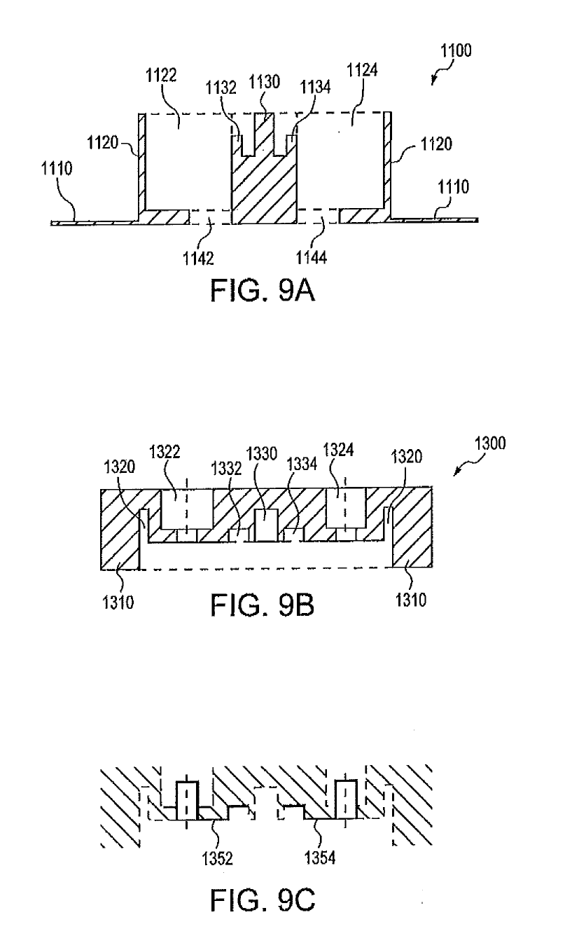

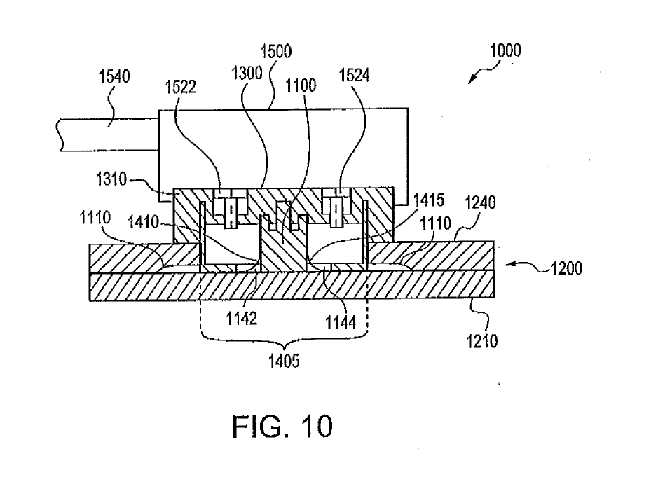

FIGS. 9A-9C show a base portion 1100, cover portion 1300, and integrated conductors 1352, 1354, respectively, of another embodiment of a conductor interface 1000 (FIG. 10). As shown in FIG. 9A, base portion 1100 includes a flange 1110 extending outwardly around its circumference, which may be a substantially flat narrow portion configured to be affixed to an interior surface of a back plate 1240 of a module 1200 around an opening 1405 in back plate 1240 (FIG. 10). First and second openings 1142, 1144 extend from a bottom surface of base portion 1100 into respective cavities 1122, 1124 formed between circumferential side wall 1120 and middle portion 1130. Middle portion 1130 also includes tab surfaces 1132, 1134 that serve as retention surfaces for holding conductive tabs 1410, 1415 (FIG. 10), respectively, in position prior to affixing cover portion 1300 (FIG. 9B) to base portion 1100. For example, tab surfaces 1132, 1134 may be raised surfaces over which conductive tabs 1410, 1415 connected to positive and negative internal busses within a PV module 1200 (FIG. 10) can be folded, respectively, in order to retain tabs 1410, 1415 in position.

As shown in FIG. 9B, cover portion 1300 includes a circumferential wall 1310 that serves as an exterior wall of conductor interface 1000. Cover portion 1300 also includes a slot 1320 for mating with circumferential wall 1120 of base portion 1100, a slot 1330 for mating with surface 1130 of base portion 1100, and slots 1332, 1134 for mating with tab surfaces 1132, 1134 of base portion 1100. Base portion 1100 and cover portion 1300 can also include a retention feature (e.g., retention feature 275 discussed above in connection with FIGS. 5A-5E) such as, for example, a snap, clip, lock, seal, fastener, press fit, friction fit, or snap fit, to affix cover portion 1300 to base portion 1100.

Cover portion 1300 also includes openings 1322, 1324 that provide a path for conductors 1352, 1354 (FIG. 9C) to provide an external electrical connection, such as to external conductors provided at a connector assembly 1500 (FIG. 10) that can be mounted on top of conductor interface 1000. In another embodiment where connector assembly 1500 is not used, external wires or other electrical conductors may be inserted through openings 1322, 1324 to connect to the conductors 1352, 1354.

FIG. 9C shows conductors 1352, 1354 that may be integrated into cover portion 1300. Conductors 1352, 1354 may be formed of metal or other conductive materials, and may be formed as a metal trace in cover portion 1300 or attached as a separate piece. Conductor 1352 is configured to provide an operable electrical connection to conductive tab 1410 of module 1210 through opening 1322. Conductor 1354 is configured to provide an operable electrical connection to conductive tab 1415 of module 1210 through opening 1324. Conductors 1352, 1354 provide an electrical connection between conductive tabs 1410, 1415 of module 1200 (FIG. 10) and receptors 1522, 1524, respectively, of a connector assembly 1500 (FIG. 10) when the connector assembly 1500 is mounted on top of conductor interface 1000. Conductor 1352 is configured to cover tab surface 1132 and extend upwards through opening 1322. Conductor 1354 is configured to cover tab surface 1134 and extend upwards through opening 1324.

FIG. 10 shows a cross-sectional view of a PV module 1200 with conductor interface 1000 including base portion 1100, cover portion 1300, integrated conductors 1352, 1354 described above in connection with FIGS. 9A-9C, and connector assembly 1500 mounted to cover portion 1300.

As shown in FIG. 10, base portion 1100 is incorporated into opening 1405 in back plate 1240 of module 1200. Base portion 1100 includes a flange 1110 that is located beneath back plate 1240, for example, between an interior surface of back plate 1240 and a module interlayer 235 (FIG. 2). During manufacture of module 1200, flange 1110 of base portion 1000 may be bonded to an inside surface of back plate 1240 prior to affixing back plate 1240 to module 1200. Flange 1110 may be sealed to the interior surface of back plate 1240 using a sealant such as a silicon sealant, an epoxy, or other appropriate sealant in order to provide a moisture seal for module 1200.

First and second conductive tabs 1410, 1415, which connect to internal module busses, extend through openings 1142, 1144 of base portion 1100. Tabs 1410, 1415, are folded over tab surfaces 1132, 1134, and their lengths adjusted (e.g., trimmed) if necessary.

Cover portion 1300 can be affixed to base portion 1100 after back plate 1240 has been affixed to the sub-assembly of module 1200. An adhesive, a sealant, an ultrasonic welding process, or other methods can be used to affix cover portion 1300 to base portion 1100. In another embodiment, a retention feature (e.g., retention feature 275 discussed above in connection with FIGS. 5A-5E) such as, for example, a snap, clip, lock, seal, fastener, press fit, friction fit, or snap fit, can be used to affix cover portion 1300 to base portion 1100.

When cover portion 1300 is affixed to base portion 1100, the portion of conductor 1352 configured to cover tab surface 1132 provides an operable electrical connection between tab 1410 and the portion of conductor 1352 extending into opening 1322. The portion of conductor 1354 configured to cover tab surface 1134 provides an operable electrical connection between tab 1415 and the portion of conductor 1354 extending into opening 1324. Potting material may then be injected into conductor interface 1000 to fill, or nearly fill, the interior of conductor interface 1000.

Connector assembly 1500 (FIG. 10) can then be connected to the assembled conductor interface 1000. Connector assembly 1500 may be, for example, a wiring harness or other device configured to electrically interconnect multiple PV modules (e.g., in a series or parallel connection) or other electrical devices. Connector assembly 1500 may include, for example, conductive receptors 1522, 1524 that are electrically connected to respective conductors 1352, 1354 within or at a top surface of openings 1322, 1324, respectively. Conductive receptors 1522, 1524 are respectively connected to a pair of external conductors, shown collectively as conductors 1540, which may be part of a wiring harness. Connector assembly 1500 may be configured to snap into place on cover portion 1300, for example using a spring loaded assembly or other retention mechanism.

Conductor interface 1000 can provide a low profile interconnection to PV module 1200. For example, base portion 1100 can be configured to protrude above an exterior surface of back plate 1240 in a range of 1-10 millimeters, and in particular, a range of 3-5 millimeters, with the top side of cap portion 1300 which does not mate with base portion 1100 (e.g., the height of cap portion 1300 above the top of slots 1320 and/or 1330) protruding an additional height in a range of 0.1-2 millimeters.

Conductor interface 1000 eliminates the need to solder conductors to tabs 1410, 1415, providing an efficient manufacturing process while reliably maintaining a desired position for tabs 1410, 1415. Conductor interface 1000 can also reduce manufacturing and deployment costs of PV modules. Fewer components are needed to create an electrical connection to PV module 1200, e.g., by electrically connecting conductor interface 1000 to connector assembly 1500. In addition, conductor interface 1000 provides a low profile PV module 1200 because conductor interface 1000 protrudes less than a comparable-sized conductor interface affixed to an exterior surface of the back plate 1240, allowing for efficient stacking of multiple PV modules during storage or transport.

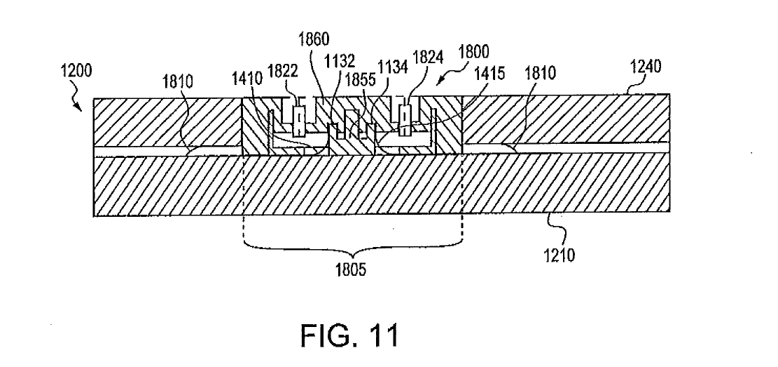

FIG. 11 shows a cross-sectional view of module 1200 including another embodiment of a conductor interface 1800. Conductor interface 1800 includes a base portion 1855 and cover portion 1860 that are both designed to substantially entirely fit within an opening in back plate 1240, such as an opening 1805 that exposes tabs 1410, 1415. As with conductor interface 1000 described with reference to FIG. 10, base portion 1855 of conductor interface 1800 is connected by a flange 1810 to an interior surface of back plate 1240 and/or to one or more interior layers of module 1200, such as an interlayer 235 (FIG. 2). First and second tabs 1410, 1415 are folded over first and second tab surfaces 1132, 1134 of base portion 1855 and are electrically connected to conductors 1822, 1824, respectively. Although not shown in FIG. 11, a connector assembly 1500 (FIG. 10) may be electrically connected to the PV module 1200 by conductors 1822, 1824. Conductor interface 1800 does not substantially protrude from back plate 1240, providing a PV module 1200 with a substantially flush back plate 1240 for even further efficiency in stacking of multiple PV modules during storage or transport.

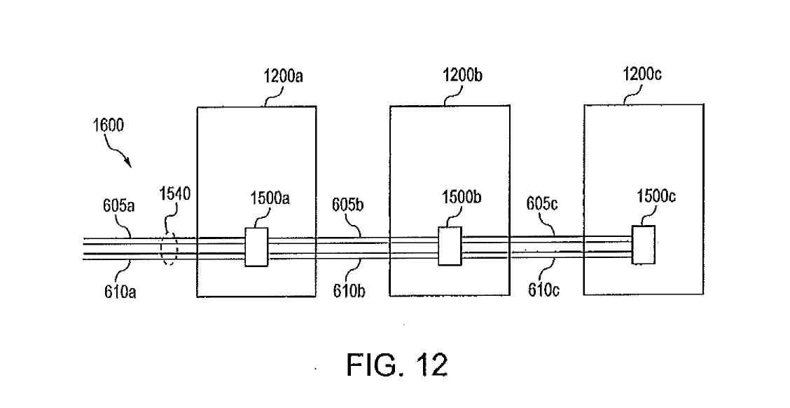

FIG. 12 illustrates a top-down view of PV modules 1200a, 1200b, 1200c electrically connected by respective connector assemblies 1500a, 1500b, 1500c that form part of a wiring harness 1600. Each respective connector assembly is configured to electrically connect to a conductor interface (e.g., conductor interface 1000 of FIG. 10) on the respective PV module 1200a, 1200b, 1200c. Conductive receptors 1522, 1524 (FIG. 10) of each respective connector assembly 1500a, 1500b, 1500c provide an electrical connection from conductors 1352, 1354 in the connected conductor interface 1000 to respective external conductors 605a, 610a, 605b, 610b, 605c, 610c, respectively. External conductors 605a, 610a, 605b, 610b, 605c, 610c may be any appropriate wires or cables known in the art, and may include insulating jackets surrounding their conductive core, similar to external conductors 605, 610 described in connection with FIGS. 4C-4D, 5D-5E, 6, and 7.

Details of one or more embodiments are set forth in the accompanying drawings and the above description. Other features, objects, and advantages will be apparent from the description, drawings, and claims. Although a number of specific embodiments of the invention have been described, it will be understood that various modifications may be made without departing from the spirit and scope of the invention.

Features described with reference to one specific embodiment are not to be understood to be limited to that embodiment. For example, retention surfaces 1132, 1134 of conductor interface 1000 described above with reference to FIGS. 8-9 may also include one or more textured surfaces, such as those described above with reference to FIGS. 3-7. Numerous other examples will be readily apparent to one of skill in the art in light of the disclosure herein. Accordingly, the scope of the described invention is not limited to the specific embodiments described above, but only by the scope of the appended listing of claims.

What is claimed as new and desired to be protected by Letters Patent of the United States is:

1. A conductor interface for a photovoltaic module, said conductor interface comprising:
a base portion comprising a bottom surface and an opening in said bottom surface configured to receive a module conductor; and
a cover portion for engagement with said base portion,
wherein at least one of said base portion and said cover portion comprises a retention surface configured to retain said module conductor in position when said base portion is engaged with said cover portion.

2. The conductor interface of claim 1, wherein said base portion is further configured to receive a second module conductor, and wherein at least one of said base portion and said cover portion further comprises a second retention surface configured to retain said second module conductor in position when said base portion is engaged with said cover portion.

3. The conductor interface of claim 1, further comprising a retention feature configured to retain said cover portion in engagement with said base portion.

4. The conductor interface of claim 1, wherein said retention surface comprises a textured surface.

5. The conductor interface of claim 4, wherein said textured surface comprises one of a plastic material and a fabric material.

6. The conductor interface of claim 4, wherein said textured surface is a conductive surface.

7. The conductor interface of claim 1, wherein said retention surface is configured to retain said module conductor such that said module conductor is electrically connected to another conductor when said base portion is engaged with said cover portion.

8. The conductor interface of claim 1, wherein said base portion comprises said retention surface, and wherein said cover portion comprises a second retention surface arranged in a location corresponding to said retention surface, wherein said retention surface and said second retention surface are configured to retain said module conductor and an external conductor in position when said base portion is engaged with said cover portion.

9. The conductor interface of claim 8, wherein said second retention surface is configured to engage with said retention surface and said retention surface and said second retention surface are configured to retain said module conductor such that said module conductor is electrically connected to said external conductor when said base portion is engaged with said cover portion.

10. The conductor interface of claim 2, wherein said base portion comprises said retention surface and said second retention surface, said cover portion comprising:
a third retention surface arranged in a location corresponding to said retention surface, wherein said retention surface and said third retention surface are configured to retain said module conductor and a first external conductor in position when said base portion is engaged with said cover portion; and
a fourth retention surface arranged in a location corresponding to said second retention surface, wherein said second retention surface and said fourth retention surface are configured to retain said second module conductor and a second external conductor in position when said base portion is engaged with said cover portion.

11. The conductor interface of claim 1, said base portion further comprising a flange for engaging with said interior surface of said photovoltaic module.

12. The conductor interface of claim 1, wherein said retention surface comprises a raised surface on said base portion configured to retain said module conductor when said module conductor is folded over said raised surface.

13. The conductor interface of claim 1, further comprising a trace configured to provide an electrical connection to an external conductor.

14. A photovoltaic module comprising:
a back plate including an opening exposing at least one module conductor;
a conductor interface affixed to said back plate, said conductor interface comprising a base portion that is configured to receive the at least one module conductor and to engage with a cover portion,
wherein at least one of said base portion and said cover portion comprises a retention surface configured to retain said at least one module conductor in position when said base portion is engaged with said cover portion.

15. The photovoltaic module of claim 14, wherein said base portion comprises said retention surface and said cover portion comprises a second retention surface configured to engage with said retention surface.

16. The photovoltaic module of claim 14, wherein said retention surface comprises a textured surface.

17. The photovoltaic module of claim 14, wherein a bottom surface of said base portion is affixed to an exterior surface of said back plate.

18. The photovoltaic module of claim 14, wherein said base portion is affixed to an interior surface of said back plate.

19. A method of manufacturing a photovoltaic module, said method comprising:
providing a sub-assembly of a photovoltaic module, said sub-assembly including an exposed module conductor electrically connected to an internal bussing system of said photovoltaic module;
affixing a base portion of a conductor interface to said sub-assembly such that an opening in said base portion receives said exposed module conductor;
arranging said exposed module conductor to contact a retention surface on said base portion; and
engaging a cover portion of said conductor interface with said base portion such that said retention surface retains said exposed module conductor in position.

20. The method of claim 39, said cover portion comprising a second retention surface configured to engage with said retention surface, said method further comprising:
clamping said retained module conductor and an external conductor between said retention surface and said second retention surface.
